(19) United States
(12) Patent Application Publication
(10) Pub. No.: US 2009/0084308 A1
(43) Pub. Date: Apr. 2, 2009

(54) Easily crystallizable vitreous silica member, vitreous silica crucible and method for manufacturing single-crystal silicon

(75) Inventors: Hiroshi KISHI, Akita-ken (JP); Minoru KANDA, Akita-shi (JP)

Correspondence Address: GREENBLUM & BERNSTEIN, P.L.C., 1950 ROLAND CLARKE PLACE, RESTON, VA, 20191, US

(73) Assignee: JAPAN SUPER QUARTZ CORPORATION, Akita-ken (JP)

(21) Appl. No.: 12/143,046

(22) Filed: Jun. 20, 2008

(30) Foreign Application Priority Data
Dec. 30, 2005 (JP) 2005-346335

(51) Int. Cl. C30B 15/00; C01B 33/12

(52) U.S. Cl. 117/13; 117/208; 423/335

(57) ABSTRACT

A vitreous silica member of the present invention is characterized by being formed of vitreous silica exhibiting the easily crystallizable property in the absence of a crystallization accelerator. The vitreous silica having the easily crystallizable property is obtained preferably by heating and melting crystalline quartz at a temperature in the range of 1,710° C. or more to 1,780° C. or less for vitrification, and controlling the fictive temperature of the glass to be in the range of 1,100° C. or more to 1,400° C. or less. The invention also includes a vitreous silica crucible and a method of pulling single-crystal silicon using this vitreous silica crucible.

### BACKGROUND OF THE INVENTION

1. Field of the Invention

The present invention relates to a vitreous silica member which has a property of being easily crystallized when no crystallization accelerator is included, a vitreous silica crucible employing the same, and a method of pulling a single-crystal silicon.

2. Description of Related Art

Single-crystal silicon which is used as a semiconductor material such as a silicon wafer is mainly manufactured by a Czochralski method (CZ method) including: heating and melting polycrystalline silicon in a vitreous silica crucible, to give a silicon melt; growing a single crystal centering around a seed crystal which is dipped into the melt surface under high temperature; and gradually pulling to grow rod-shaped single-crystal silicon.

The vitreous silica crucible used for pulling the single-crystal silicon is exposed to a high temperature of 1,400° C. or higher upon pulling. At this high temperature of 1,400° C. or higher, the wall part of the crucible often sinks down or collapses inward, which thereby causes problems such as a decrease in a single crystal yield and leakage of the silicon melt. As a measure against this, there has been known a technique for enhancing the strength of a crucible by either applying compounds such as Ba or Al as a crystallization accelerator to the crucible surface, or doping vitreous silica forming the crucible, which allows the crucible to crystallize the vitreous silica under high temperature (Patent Document 1: Japanese Patent No. 3054362, Patent Document 2: Japanese Patent No. 3100836). However, in this method, a decrease in the purity of single-crystal silicon cannot be avoided because the element serving as a crystallization accelerator becomes mixed in with the silicon melt thereby generating impurities

Meanwhile, as a method for enhancing the strength of a crucible by facilitating the crystallization of vitreous silica without the use of a crystallization accelerator, a method of coating the outer surface with the silica powder formed into slurry has been developed (Patent document 3: Japanese Unexamined Patent Application No. 2004-131317). According to this method, there is no concern that a crystallization accelerator which forms an impurity mixes in the silicon melt due to the use of the silica powder, thus the method has the advantage of allowing the manufacture of highly pure single-crystal silicon. However, there may be a case where the silica powder coated on the surface of a crucible exfoliates and mixes into the silicon melt, and as a result, crystallization of single-crystal silicon is affected. Therefore, it is expected to increase the degree of single crystallization by resolving this problem.

### SUMMARY OF THE INVENTION

The present invention has resolved the above-mentioned problems in a silica glass member like a conventional vitreous silica crucible or the like, and problems such as sinking down or collapsing inward of the wall part of a crucible under high temperature or decrease in the purity due to the use of a crystallization accelerator are resolved by using vitreous silica provided with a property of being easily crystallized under high temperature in the absence of a crystallization accelerator. The invention can be widely applied to vitreous silica members to be used under high temperature, and is not limited to vitreous silica crucibles. In the invention, a property of easily undergoing crystallization at high temperature in the absence of a crystallization accelerator is referred to as the easily crystallizable property.

According to the invention, a vitreous silica member which has resolved the above-mentioned problems by the constitutions described below and its application are provided.

(1) A vitreous silica member characterized by being formed of vitreous silica exhibiting the easily crystallizable property in the absence of a crystallization accelerator.

(2) The vitreous silica member described in the above (1), which is formed of quartz glass provided with the easily crystallizable property by heating and melting crystalline quartz at a temperature in the range of 1,710° C. or more to 1,780° C. or less for vitrification, followed by controlling the fictive temperature of the glass to be in the range of 1,100° C. or more to 1,400° C. or less.

(3) The vitreous silica member described in the above (1) or (2), in which the whole member or a part of the member is formed of vitreous silica exhibiting the easily crystallizable property in the absence of a crystallization accelerator.

(4) A vitreous silica crucible used for pulling single-crystal silicon, in which a whole or a part of the vitreous silica crucible is formed of the vitreous silica described in any one of the above (1) to (3).

(5) The vitreous silica crucible described in the above (4), in which at least the surface layer of the vitreous silica crucible is formed of vitreous silica exhibiting the easily crystallizable property in the absence of a crystallization accelerator.

(6) The vitreous silica crucible described in the above (5), in which the wall part, curved part, or at least outer surface layer of the wall part of the vitreous silica crucible is formed of vitreous silica exhibiting the easily crystallizable property in the absence of a crystallization accelerator.

(7) The vitreous silica crucible described in any one of the above (4) to (6), in which the inner surface layer of the vitreous silica crucible is formed of synthetic fused silica, and at least the outer surface layer of the wall part of the crucible is formed of quartz glass for which natural quartz is vitrified and which exhibits the easily crystallizable property in the absence of a crystallization accelerator.

(8) A method for manufacturing single-crystal silicon using the vitreous silica crucible described in any one of the above (4) to (7).

According to the invention, there will be no problem caused by a crystallization accelerator which forms an impurity because a vitreous silica member is formed of vitreous silica exhibiting the property of being easily crystallized under high temperature in the absence of a crystallization accelerator. For example, in the case of applying to a vitreous silica crucible which is used for pulling single-crystal silicon, highly pure single-crystal silicon can be obtained.

A quartz glass to be used for the vitreous silica member of the invention is obtained by heating and melting crystalline quartz at a temperature in the range of 1,710° C. or more to 1,780° C. or less, preferably 1,730° C. or more to 1,750° C. or less for vitrification, thereby providing the easily crystallizable property, more specifically, obtained by controlling the vitrification temperature of quartz powder which is a raw material. Thus, it is easy to put into practice. Moreover, the invention can be easily applied to a vitreous silica crucible manufactured by heating and melting silica powder.

Furthermore, according to the method for manufacturing single-crystal silicon of the invention, highly pure single-crystal silicon can be obtained, thereby achieving a high degree of single crystallization, without a problem of an impurity such as a crystallization accelerator mixing into a silicon melt upon pulling a single crystal since an element forming the impurity is not included in the vitreous silica crucible.

Natural quartz is a raw material which can be obtained by mining raw quartz stones occurring in nature and subjecting them to the processes of crushing and purification. Synthetic silica is manufactured from a chemically-synthesized material. Since the material is gas or liquid, the synthetic silica can be easily purified, thereby obtaining a much higher purity than that of natural quartz powder. As the raw material for the synthetic fused silica, there are gaseous raw materials such as carbon tetrachloride and liquid raw materials such as silicon alkoxide.

Natural quartz powder is composed of an α-quartz crystal, and synthetic fused silica powder is composed of an amorphous material.

Natural quartz powder contains 1 ppm or more of Al or Ti. Other metal impurities are also contained at a higher level than in synthetic silica powder. On the other hand, it is possible to set the total impurities to be 0.1 ppm or less in synthetic fused silica.

Natural quartz powder contains almost no silanol, but in synthetic fused silica powder produced by a sol-gel method, 50 to 100 ppm silanol, which is formed by hydrolysis of alkoxide, remains usually. With regard to carbon tetrachloride-based synthetic fused silica, silanol can be controlled in a wide range of 0 to 1,000 ppm, but generally chloride of 100 ppm or more is contained. In the case of using alkoxide as a raw material, synthetic fused silica containing no chloride can be easily obtained.

The synthetic fused silica powder produced by the sol-gel method contains approximately 50 to 100 ppm silanol before melting as mentioned above. When this is melted in a vacuum, silanol desorbs, and silanol in the vitreous silica to be obtained decreases to the range of about 5 to 30 ppm. The silanol amount varies according to melting conditions such as melting temperature and rising temperature. The silanol amount of glass which is obtained by melting natural quartz powder under the same conditions is less than 5 ppm.

It is generally said that the viscosity of the synthetic fused silica at high temperature is lower than that of the quartz glass obtained by melting natural quartz powder. One of the reasons for this is that silanol or halogen disrupts a network structure of SiO₄ tetrahedron.

When measuring the light transmittance, it rapidly falls in the case where the wavelength becomes 250 nm or shorter, and light hardly transmits in the case of a wavelength of 200 nm, because glass obtained from natural quartz powder includes Ti having approximately 1 ppm mainly as the impurity. An absorption peak resulting from oxygen defects is shown near 245 nm. Meanwhile, glass which is obtained by melting synthetic fused silica transmits ultraviolet rays well to the wavelength of approximately 200 nm. Consequently, it is considered that glass is close to the property of synthetic fused silica using carbon tetrachloride as a raw material, which is used for ultraviolet optics applications.

When measuring the fluorescence spectrum obtained by exciting with ultraviolet rays of the wavelength of 245 nm, the fluorescence peak is observed at 280 nm and 390 nm in molten products of natural quartz powder. These fluorescence peaks are caused by oxygen defects in glass. As for glass obtained by melting synthetic fused silica powder, a fluorescence peak is not observed.

### BRIEF DESCRIPTION OF THE DRAWINGS

FIG. 1 is a sectional view showing one embodiment of a manufacturing device for a vitreous silica member related to the invention.

FIG. 2 is a sectional view showing one embodiment of a vitreous silica crucible related to the invention.

FIG. 3 is a sectional view showing another embodiment of a vitreous silica crucible related to the invention.

### DETAILED DESCRIPTION OF THE INVENTION

Generally, crystalline quartz (α-Quartz) varies in a crystalline form depending on a heating temperature, for example, it turns into β-Quartz near 573° C., and β-Tridymite near 870° C., β-Cristobalite near 1,470° C., and melts under high temperature of 1,700° C. or higher to become glass.

A vitreous silica member is usually manufactured by heating and melting crystalline quartz powder of a raw material at a temperature of 1,700° C. or higher for vitrification, followed by slowly cooling in a vitrified state. In the case where this vitreous silica member is exposed to high temperature in the range of 1,400° C. or more to less than 1,700° C. (below melting temperature), the glass phase recrystallizes with partial phase transition since this temperature range is stable for silica as a β-Cristobalite crystal.

The present inventors have found that there was a sharp contrast in the speed of recrystallization of glass at a temperature for vitrifying quartz powder (crystalline quartz) and at a fictive temperature of glass when a quartz glass member which is vitrified by heating and melting quartz powder (crystalline quartz) was exposed to high temperature in the range of 1,400° C. or more to less than 1,700° C. (below melting temperature). The fictive temperature is an indicative temperature showing the structural stability of vitreous silica, and it means a temperature before quenching under the condition that quasi-equilibrium glass which is stable at a sufficiently high temperature is quenched to normal temperature at an infinite speed. The invention forms a vitreous silica member by controlling this vitrification temperature and fictive temperature using vitreous silica which is easily crystallized at high temperature in the absence of a crystallization accelerator.

In the invention, the temperature vitrifying quartz powder (crystalline quartz) is preferably in the range of 1,710° C. or more to 1,780° C. or less, more preferably in the range of 1,730° C. or more to 1,750° C. or less since the speed of recrystallization is higher. As shown in comparative examples below, crystalline quartz is heated at 1,800° C. to vitrify, which has a slow speed of recrystallization and the crystal layer becomes thin. Meanwhile, when the heating temperature is lower than 1,700° C., a vitreous silica member is not formed since the crystalline quartz is not vitrified.

Furthermore, easily crystallizable vitreous silica of the invention is obtained by controlling the fictive temperature to become a glass state after melting in the range of 1,100° C. or more to 1,400° C. or less as well as quartz powder (crystalline quartz) being melted within the range of heating temperature described above. As shown in comparative examples below, when the fictive temperature to become a glass state after melting is outside the range of the above-mentioned temperature, the speed of recrystallization becomes slow and the crystal layer becomes thin.

The fictive temperature is determined by the cooling speed, consequently, the fictive temperature can be controlled by controlling the cooling speed. As a specific method, there are a method of controlling the distance between the carbon electrode which is under arc discharge and the crucible, and a method of introducing cooling gas, in which the temperature and the flow rate are controlled, from a hole for vacuuming in the mold, and the like.

For a method for measuring the fictive temperature, for example, the following method using a Raman spectrophotometer is possible. First, four pieces of synthetic fused silica are prepared as standard specimens. The first piece is heated at 1,200° C. for 2 hours and then quenched under water to set a specimen 1, the second piece is heated at 1,000° C. for 20 hours and then quenched under water to set a specimen 2, the third piece is heated at 900° C. for 120 hours and then quenched under water to set a specimen 3, and the fourth piece is heated at 800° C. for 1,200 hours and then quenched under water to set a specimen 4.

Next, these standard specimens 1 to 4 are placed into a Raman spectrophotometer respectively, measured in the range of 150 to 650 cm⁻¹ and three peaks described below are determined.

150 to 650 cm⁻¹ (Peak Area W1)

470 to 520 cm⁻¹ (Peak Area D1)

580 to 640 cm⁻¹ (Peak Area D2)

Next,

Area Ratio I={D2÷(W1−D1−D2)}

is calculated from these three Peak Areas, the relationship between Area Ratio I of each standard specimen 1 to 4 and each fictive temperature (standard specimen 1: 1,200° C., standard specimen 2: 1,000° C., standard specimen 3: 900° C., and standard specimen 4: 800° C.) is plotted on a graph, and a calibration curve is obtained. Then, specimens to measure a fictive temperature are measured by the Raman spectrophotometer, and fictive temperatures are measured from the calculated Area Ratio I.

vitreous silica which is easily crystallized has an irregular glass structure in macroscopic observation, but in microscopic observation, regularly arranged crystal layers are observed at a small part. Therefore, when this vitreous silica is used under high temperature of 1,400° C. or higher and below the melting temperature, this crystal layer which partially remains becomes a nucleus and crystallization proceeds. Accordingly, it is considered that the speed of crystallization is high and the vitreous silica exhibits an easily crystallizable property.

Since the time required for melting quartz powder and keep heating it is very short, not all the crystal structure (α-Quartz) turns into a glass structure at a temperature of 1,780° C. or lower. When the outer surface of a crucible practically produced is analyzed by X-ray diffraction, α-Quartz is detected.

A vitreous silica member of the invention may be entirely formed of vitreous silica exhibiting the easily crystallizable property in the absence of a crystallization accelerator, but instead of this, a part of the member, for example, only the surface layer of the member may be formed of vitreous silica exhibiting the easily crystallizable property in the absence of a crystallization accelerator. The surface layer means the range from the surface of a member to 10% thickness of a member. If not only the whole member, but a part of the member, for example, the surface of the member, is formed of vitreous silica which is easily crystallized, the strength of the member can be enhanced since crystallization proceeds from the surface of the member when using under high temperature described above.

Incidentally, since the layer of primordial crystalline quartz is formed before the vitrification of crystalline quartz likely to cause microscopic cracks due to expansion and shrinkage of volume when the crystal form is transformed under the high temperature, consequently, it does not attribute to the improvement of the strength of a glass member.

As a kind of vitreous silica member, in a general method for manufacturing a vitreous silica crucible, first, silica powder is accumulated to a fixed thickness on the inner surface of a rotary mold, and the layer of this silica powder is heated at a melting temperature or higher to vitrify. After cooling, the resultant product is taken out of the mold. The vitreous silica crucible of the invention is characterized in that after controlling the fictive temperature of silica powder of a raw material to be 1,100° C. or more and 1,400° C. or less, the silica powder of a raw material is accumulated on the inner surface of the rotary mold, heated and melted at 1,710° C. or more and 1,780° C. or less, preferably 1,730° C. or more and 1,750° C. or less to vitrify.

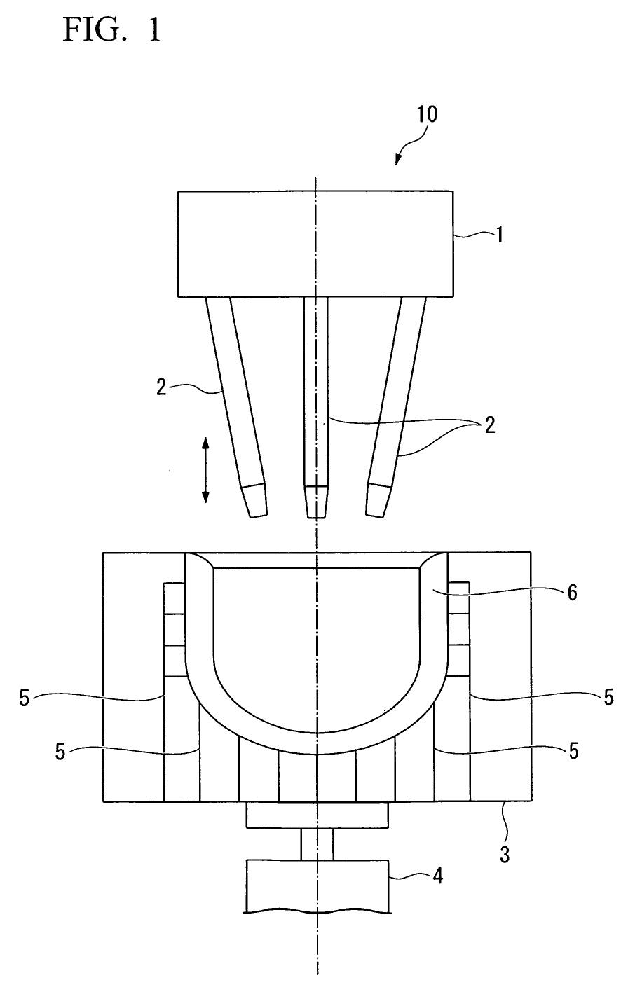

FIG. 1 shows an example of a usable manufacturing device of a vitreous silica crucible in the invention. This device is mainly constituted of a bottomed cylindrical mold 3, a drive mechanism 4 rotating the mold 3 around the axis, and an arc discharge device 10 in order to heat inside of the mold 3. The mold 3 is formed of, for example, carbon, and a number of pressure reducing passages 5 which open on the inner surface of the mold are formed inside. A pressure reducing mechanism not shown in the figures is connected to the pressure reducing passage 5, and the mold 3 can inhale from the inner surface through the pressure reducing passage 5 as soon as it is rotated. Inside the mold 3, a silica deposited layer 6 can be formed by accumulating quartz powder. This silica deposited layer 6 can be held on the inner wall surface by a centrifugal force of rotation of the mold 3. By reducing pressure through the pressure reducing passage 5 while the held silica deposited layer 6 is heated by the arc discharge device 10, the silica deposited layer 6 is melted to form a vitreous silica layer. After cooling, a vitreous silica crucible is taken out of the mold 3 and the shape is arranged, thereby producing the vitreous silica crucible.

The arc discharge device 10 is equipped with a plurality of carbon electrodes 2 which are formed of highly pure carbon and are in a rod shape; an electrode moving mechanism 1 which holds the carbon electrodes 2 while moving them; and a power unit (not shown in FIGS.) for supplying electrical current to each carbon electrode 2. In this example, the moving mechanism 1 has three carbon electrodes 2, but it may have two or four or more because it has only to conduct arc discharge among the carbon electrodes 2. The shape of the carbon electrode 2 is not limited as well. The carbon electrodes 2 are placed to come close to each other toward the tips. The power supply may be alternating current or direct current, but in this embodiment, each phase of three-phase alternating current is connected to three carbon electrodes 2.

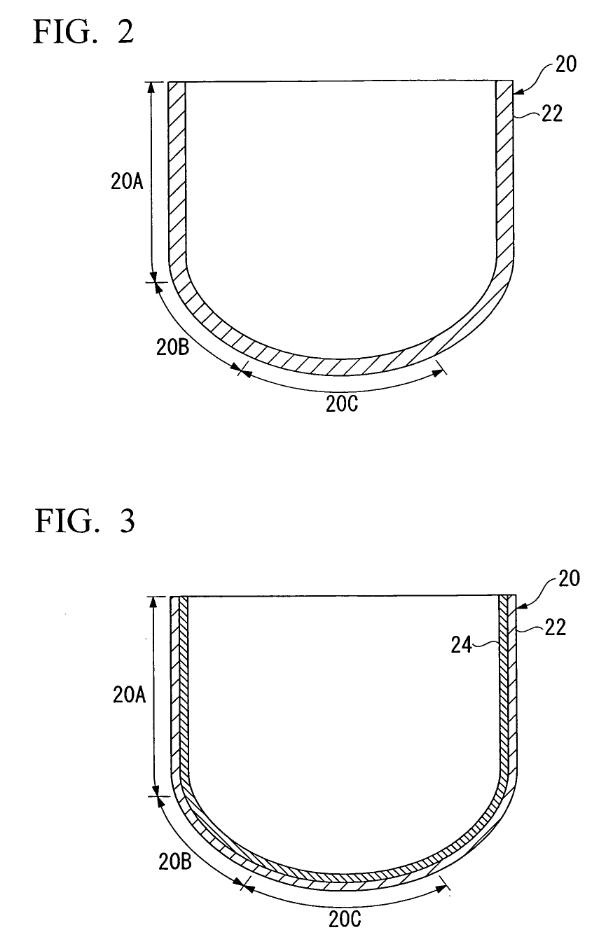

FIG. 2 shows an example of a vitreous silica crucible. This vitreous silica crucible 20 is constituted of a wall part 20A, a curved part 20B and a bottom 20C, and formed of vitreous silica 22 exhibiting the easily crystallizable property in the absence of a crystallization accelerator.

The vitreous silica crucible of the invention can be formed in various aspects: (A) the whole (or a part of the) crucible is formed of the above vitreous silica 22 exhibiting the easily crystallizable property in the absence of a crystallization accelerator as one embodiment shown in FIG. 2; (B) at least the surface layer of the crucible is formed of the above vitreous silica exhibiting the easily crystallizable property in the absence of a crystallization accelerator; and (C) the wall part 20A, the curved part 20B, or at least the outer surface layer of the wall part 20A of the crucible is formed of the above vitreous silica 22 exhibiting the easily crystallizable property in the absence of a crystallization accelerator.

FIG. 3 shows another embodiment of a vitreous silica crucible. This vitreous silica crucible 20 is constituted by a wall part 20A, a curved part 20B and a bottom 20C, wherein the inner surface layer is formed of synthetic fused silica 24, and the outer surface layer is formed of vitreous silica 22 for which natural quartz is vitrified and which exhibits the easily crystallizable property in the absence of a crystallization accelerator.

In addition, for the vitreous silica crucible of the invention, as shown in FIG. 3, (D) the inner surface layer of the vitreous silica crucible can be formed of synthetic fused silica 24, and the outer surface layer of the crucible can be formed of the above vitreous silica 22 for which natural quartz is vitrified and which exhibits the easily crystallizable property in the absence of a crystallization accelerator. In order to manufacture such a vitreous silica crucible, crystalline natural quartz powder is accumulated on the inner surface of the rotary mold, crystalline synthetic silica is accumulated on it (inner circumference side), and heated and melted at the above vitrification temperature (1,710° C. or more and 1,780° C. or less, preferably 1,730° C. or more and 1,750° C. or less). Only the outer surface layer of the wall part 20A may be formed of the vitreous silica 22 which is easily crystallized, not all parts of the outer surface layer of the crucible. Because the strength of the wall part 20 A is particularly important.

The synthetic silica powder has an average particle diameter of 350 μm, and the diameter range is 60 to 600 μm. The natural quartz powder has an average particle diameter of 250 μm, and the diameter range is 50 to 500 μm.

The conventional vitreous silica crucible has a half-melted crystalline quartz layer having a thickness of 100 to 300 μm on the outer surface of the crucible in order to take out of a mold easily. However, under the operating temperature of the crucible, when silica becomes the most stable form (β-Cristobalite), the transition from amorphous silica glass to β-Cristobalite is easier than the transition from crystalline quartz to β-Cristobalite, and the speed of recrystallization is high.

Furthermore, in a vitreous silica member, crystallization of the depth direction (wall thickness direction) is very slow compared with crystallization of the surface, and is greatly affected by the crystal condition of the surface. A vitreous silica crucible whose surface has an unstable crystal structure cannot be crystallized in the depth direction as long as the unstable crystal structure of the surface is not solved.

Accordingly, the crystalline quartz layer remaining on the outer surface of the vitreous silica crucible should be removed, and the outer surface of the crucible should be formed of the above vitreous silica which is easily crystallized. As to such a vitreous silica crucible, crystallization swiftly progresses from the outer surface of the crucible to the depth direction. Consequently, a thick and uniform crystal layer can be obtained, and the strength of the crucible is improved. In order to remove the crystalline quartz layer remaining on the outer surface of the crucible, the surface may be ground by a sandblast or heated at the vitrification temperature described above.

If the above vitreous silica crucible of the invention is used, the crucible strength is maintained at high temperature upon its use and thus collapsing inward or sinking down of the wall part of the crucible does not occur, thereby achieving a high yield of single crystal.

The present invention includes a method for manufacturing single-crystal silicon using such a vitreous silica crucible mentioned above.

In one embodiment of a method for manufacturing single-crystal silicon, a single-crystal silicon ingot is manufactured including the steps of: melting polycrystalline silicon in the vitreous silica crucible mentioned above; and immersing a seed of single-crystal silicon in a molten silicon melt, and pulling the seed while rotating the vitreous silica crucible.

Single-crystal silicon is generally manufactured by a Czochralski method. In the Czochralski method, a Si seed crystal is immersed in a Si melt to grow the crystal by pulling while rotating. The procedure is as follows. Highly pure polysilicon is charged in a silica crucible, and heated and melted by a carbon heater. A Si-seed crystal is immersed in a Si melt, the seed crystal is pulled upward while rotating to grow single-crystal silicon. Since the vitreous silica is dissolved in the Si melt upon pulling, the characteristic of the silica crucible greatly affects the characteristic and the yield rate of single-crystal silicon.

### EXAMPLES

Hereinafter, an Example and Comparative Examples are shown.

### Example and Comparative Example

A single silicon crystal was pulled by using a vitreous silica crucible which was manufactured by a rotary mold method, and the relationship among the vitrification temperature upon manufacturing, the thickness of the crystallized layer of the outer surface of the crucible after use and the yield of single crystal was examined. The results are shown in Table 1.

Specimen No. 1 is a crucible in which the melt vitrification temperature upon manufacturing the crucible is 1,800° C., and crystalline quartz powder remains on the outer surface of the crucible. Specimen No. 2 is a crucible in which the melt vitrification temperature upon manufacturing the crucible is 1,760° C., and crystalline quartz powder remains on the outer surface of the crucible though the temperature is within the range of the invention. Specimen No. 3 is a crucible in which the outer surface of the crucible is amorphous glass, but the melt vitrification temperature upon manufacturing the crucible is 1,800° C., which is a temperature beyond the scope of the invention. With regard to comparative specimens Nos. 1 to 3, the crystallized layer of the outer surface of the crucible after use has a thickness of 0.6 to 0.7 mm, and it is considerably thinner than that of specimen No. 7 of the invention.

Specimens Nos. 5 and 6 are crucibles in which the melt vitrification temperature is within the range of the invention, but the fictive temperature in the glass state is out of the range of the invention, the crystallized layer of the outer surface of the crucible after use has a thickness of 0.4 to 0.5 mm, and it is considerably thinner than that of specimen No. 7 of the invention.

Specimen No. 7 is a crucible of the invention, and the crystallized layer of the outer surface of the crucible after use was 2 mm in thickness, that is about 3 times thicker than those of comparative specimens, thereby confirming that the crystallization becomes very easy.

A crystallized layer and non-crystallized layer can be distinguished by cutting a piece of quartz out of the crucible and subjecting it to X-ray diffraction, thereby judging the structure.

TABLE 1

| | | | | Crystallized | |
|---|---|---|---|---|---|
| | | | | Layer | |
| | | | | Thickness of | |
| | | Melt | Fictive | Outer Surface | Yield Rate |
| | | Vitrification | Temperature | of Crucible | of Single |
| No. | State | Temperature | (Outer Surface) | after Use | Crystal |
| 1 | Outer Surface Crystalline | 1800° C. | — | 0.6 mm | 52% |
| | Quartz Crucible | | | | |
| 2 | Outer Surface Crystalline | 1760° C. | — | 0.6 mm | 54% |
| | Quartz Crucible | | | | |
| 3 | Outer Surface Non-Crystalline | 1800° C. | 1050° C. | 0.7 mm | 58% |
| | Vitreous Silica Crucible | | | | |
| 4 | Outer Surface Non-Crystalline | 1800° C. | 1200° C. | 0.5 mm | 55% |
| | Vitreous Silica Crucible | | | | |
| 5 | Outer Surface Non-Crystalline | 1760° C. | 1000° C. | 0.4 mm | 52% |
| | Vitreous Silica Crucible | | | | |
| 6 | Outer Surface Non-Crystalline | 1760° C. | 1430° C. | 0.5 mm | 58% |
| | Vitreous Silica Crucible | | | | |
| 7 | Outer Surface Non-Crystalline | 1760° C. | 1170° C. | 2.0 mm | 85% |
| | Vitreous Silica Crucible | | | | |

(Note) Specimens Nos. 1 to 6 are comparative examples, and No. 7 is an example.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A vitreous silica member, which is formed of vitreous silica exhibiting an easily crystallizable property in the absence of a crystallization accelerator.

2. The vitreous silica member according to claim 1, which is formed of quartz glass provided with the easily crystallizable property by heating and melting crystalline quartz at a temperature in the range of 1,710° C. or more to 1,780° C. or less for vitrification, followed by controlling a fictive temperature of the glass to be in the range of 1,100° C. or more to 1,400° C. or less.

3. The vitreous silica member according to claim 1, wherein a whole or a part of the member is formed of quartz glass exhibiting the easily crystallizable property in the absence of a crystallization accelerator.

4. A vitreous silica crucible according to claim 1, wherein the vitreous silica member is the vitreous silica crucible used for pulling single-crystal silicon, and a whole or a part of the vitreous silica crucible is formed of vitreous silica exhibiting the easily crystallizable property in the absence of a crystallization accelerator.

5. A vitreous silica crucible according to claim 3, wherein at least the surface layer of the vitreous silica crucible is formed of vitreous silica exhibiting the easily crystallizable property in the absence of a crystallization accelerator.

6. The vitreous silica crucible according to claim 5, wherein a wall part, curved part, or at least outer surface layer of the wall, of the vitreous silica crucible is formed of vitreous silica exhibiting the easily crystallizable property in the absence of a crystallization accelerator.

7. The vitreous silica crucible according to claim 4, wherein the inner surface layer of the vitreous silica crucible is formed of synthetic fused silica, and at least the outer surface layer of the wall part of the crucible is formed of quartz glass for which natural quartz is vitrified and which exhibits the easily crystallizable property in the absence of a crystallization accelerator.

8. A method for manufacturing single-crystal silicon using the vitreous silica crucible according to claim 4; the method comprising the steps of:
melting polycrystalline silicon in a crucible; and
immersing a seed of single-crystal silicon into the molten silicon melt and pulling up a single-crystal silicon ingot.
